(19) United States
(12) Patent Application Publication
(10) Pub. No.: US 2026/0293017 A1
(43) Pub. Date: Sep. 24, 2026

(54) TILED ELECTRONIC DEVICE

(71) Applicant: InnoLux Corporation, Miao-Li County (TW)

(72) Inventors: Jia-Yuan Chen, Miao-Li County (TW); Tsung-Han Tsai, Miao-Li County (TW); Kuan-Feng Lee, Miao-Li County (TW)

(73) Assignee: InnoLux Corporation, Miao-Li County (TW)

(21) Appl. No.: 19/558,466

(22) Filed: Mar. 6, 2026

(30) Foreign Application Priority Data
Mar. 20, 2025 (CN) 202510331076.0

(51) Int. Cl. H05K 5/30

(52) U.S. Cl. CPC H05K 5/30

(57) ABSTRACT

A tiled electronic device is provided and includes a first electronic module and a second electronic module adjacent to the first electronic module. The first electronic module is separated from the second electronic module by a gap along a direction. The tiled electronic device has a first region and a second region, wherein the first region has a first optical performance P1, and the second region has a second optical performance P2. The first optical performance P1 and the second optical performance P2 satisfy the following relationship: |(P1−P2)/P2|≤5%.

### BACKGROUND OF THE DISCLOSURE

### 1. Field of the Disclosure

The present disclosure relates to a tiled electronic device and particularly to a tilted electronic device having uniform optical performance.

### 2. Description of the Prior Art

With the advancement of display technologies, when multiple display devices are tiled together to form a display device with large area, a structure in a tiling gap between two adjacent display devices differs from that of the display device. As a result, the optical performance of the tiling gap is significantly different from that of the display device, leading to non-uniform optical performance across the entire tiled display device. Therefore, users are easy to perceive the presence of the tiling gap, thereby affecting visual effect.

### SUMMARY OF THE DISCLOSURE

An objective of the present disclosure is to provide a tiled electronic device to solve the issue mentioned above.

The present disclosure provides a tiled electronic device including a first electronic module and a second electronic module. The second electronic module is disposed adjacent to the first electronic module, wherein the first electronic module and the second electronic module are separated by a gap in a first direction. The tiled electronic device includes a first region and a second region, wherein the first region includes a portion of the gap, a first portion of the first electronic module adjacent to the gap, and a second portion of the second module adjacent to the gap, the second region and the first region are arranged along the first direction, and the second region includes a third portion of the first module adjacent to the first portion. The first region has a first optical performance P1, and the second region has a second optical performance P2, wherein the first optical performance P1and the second optical performance P2 satisfy a following relationship: |(P1−P2)/P2|≤5%.

In the tiled electronic device of the present disclosure, since the optical performances of the portions of the tiled electronic device corresponding to the center of the electronic module, corresponding to the gap, and corresponding to a position located between the center of the electronic module and the gap may satisfy the relationships mentioned above, the uniformity of the optical performance of the tiled electronic device may be increased to improve the visual effect of the tiled electronic device.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 schematically illustrates a cross-sectional view of a tiled electronic device according to a first embodiment of the present disclosure.

FIG. 2 schematically illustrates a cross-sectional view of measuring the optical performance of a region of the tiled electronic device according to an embodiment of the present disclosure.

FIG. 3 schematically illustrates a cross-sectional view of the tiled electronic device taken along a cross-sectional line A-A′ of FIG. 1 according to the first embodiment of the present disclosure.

FIG. 4 schematically illustrates a top view of the optical structure according to some embodiments of the present disclosure.

FIG. 5 schematically illustrates a cross-sectional view of a tiled electronic device according to a first variant embodiment of the first embodiment of the present disclosure.

FIG. 6 schematically illustrates a cross-sectional view of a tiled electronic device according to a second variant embodiment of the first embodiment of the present disclosure.

FIG. 7 schematically illustrates a cross-sectional view of a tiled electronic device according to a third variant embodiment of the first embodiment of the present disclosure.

FIG. 8 schematically illustrates a cross-sectional view of a tiled electronic device according to a fourth variant embodiment of the first embodiment of the present disclosure.

FIG. 9 schematically illustrates a cross-sectional view of a tiled electronic device according to a fifth variant embodiment of the first embodiment of the present disclosure.

FIG. 10 schematically illustrates a cross-sectional view of a tiled electronic device according to a second embodiment of the present disclosure.

### DETAILED DESCRIPTION

The contents of the present disclosure will be described in detail with reference to specific embodiments and drawings. It is noted that, for purposes of illustrative clarity and ease of understanding by the readers, the following drawings in the present disclosure are simplified schematic diagrams, and elements therein may not be drawn to scale. The numbers and sizes of the elements in the drawings are merely illustrative and are not intended to limit the scope of the present disclosure.

Certain terms are used throughout the specification and the appended claims of the present disclosure to refer to specific elements. Those skilled in the art should understand that electronic equipment manufacturers may refer to an element by different names, and this document does not intend to distinguish between elements that differ in name but not in function. In the following specification and claims, the terms “comprise”, “include” and “have” are open-ended fashion, so they should be interpreted as “including but not limited to . . . ”.

The ordinal numbers used in the specification and the appended claims, such as “first”, “second”, etc., are used to describe the elements of the claims. This does not mean that the element has any previous ordinal numbers, nor does this represent the order of a certain element and another element, or the sequence in a manufacturing method. These ordinal numbers are merely used to make a claimed element with a certain name be clearly distinguishable from another claimed element with the same name.

In addition, when one element or layer is “connected to” another element or layer, it may be understood that the element or layer is directly physically or electrically connected to the another element or layer, and alternatively, the element or layer and the another element or layer may be physically or electrically connected (indirectly) by another element or layer. On the contrary, when the element or layer is “directly connected to” the another element or layer, it may be understood that there is no intervening element or layer between the element or layer and the another element or layer. The term “connected” includes means of direct or indirect contact. Furthermore, the term “electrically connected” or “coupled” includes means of direct or indirect electrical connection.

As disclosed herein, the terms “approximately”, “essentially”, “about”, or “substantially” generally mean within 20%, 10%, 5%, 3%, 2%, 1%, or 0.5% of the reported numerical value or range. The quantity disclosed herein is an approximate quantity, that is, without a specific description of “approximately”, “essentially”, “about”, or “substantially”, the quantity may still include the meaning of “approximately”, “essentially”, “about”, or “substantially”.

The term “between a number A and a number B” is interpreted as including the number A and the number B or as including at least one of the number A and the number B, and as including other numbers between the number A and the number B.

In the present disclosure, depth, thickness, length, width, and aperture may be measured using an optical microscope (OM), a scanning electron microscope (SEM) or other approaches, but not limited thereto.

In the present disclosure, the definition of roughness may be a peak-to-valley distance of 0.15 μm to 1 μm of surface undulations observed by a SEM. The measurement of determining the roughness may include using a SEM or a transmission electron microscope (TEM), etc. to observe peaks and valleys of surface undulations in a proper magnified ratio, and comparing the surface undulations by taking a unit length (e.g., 10 μm) to obtain its roughness range. Here, the term “proper magnified ratio” means at least one surface may be observed a roughness (Rz) or an averaged roughness (Ra) with at least 10 peaks in the visual field in this magnified ratio.

It should be understood that, according to the following embodiments, features of different embodiments may be replaced, recombined or mixed to constitute other embodiments without departing from the spirit of the present disclosure. The features of various embodiments may be mixed arbitrarily and used in different embodiments without departing from or conflicting with the spirit of the present disclosure.

Unless otherwise defined, all terms (including technical and scientific terms) used herein have the same meaning as commonly understood by those skilled in the art. It should be understood that these terms, such as those defined in commonly used dictionaries, should be interpreted as having meaning consistent with the relevant technology and the background or context of the present disclosure, and should not be interpreted in an idealized or excessively formal way, unless there is a specific definition in the embodiments of the present disclosure.

A tiled electronic device of the present disclosure may include, for example, a display device, light emitting device, sensing device, antenna device, touch device, package device or other suitable electronic device. The tiled electronic device may be a bendable, stretchable, foldable, rollable and/or flexible electronic device, but not limited thereto. The display device may, for example, be applied to a laptop, a public display, a tiled display, a car display, a touch display, a TV, a monitor, a smartphone, a tablet, a light source module, a lighting equipment, a military equipment, or an electronic device applied to the aforementioned products, but not limited thereto. The sensing device may, for example, include a bio-sensor, a touch sensor, a fingerprint sensor, other suitable sensors, or any combination of the aforementioned sensors. The display device may include liquid crystal molecules, a light emitting diode, a fluorescent material, a phosphor material, other suitable display media, or a combination thereof, but not limited thereto. The light emitting diode may, for example, include an organic light emitting diode (OLED), a mini light emitting diode (mini LED), a micro light emitting diode (micro LED), a quantum dot light emitting diode (e.g., QLED or QDLED), other suitable material, or any combination thereof, but not limited thereto. The antenna device may include liquid crystal antenna, varactor diode antenna, or antennas of other types, but not limited thereto. The tiled device may include a tiled display device or a tiled antenna device, but not limited thereto. Furthermore, the appearance of the electronic device may be, for example, rectangular, circular, polygonal, a shape with curved edges, curved or other suitable shapes. The electronic device may have peripheral systems such as a driving system, a control system, a light source system, a shelf system, etc. It is noted that the tiled electronic device of the present disclosure may be any combination of the above-mentioned devices, but not limited thereto.

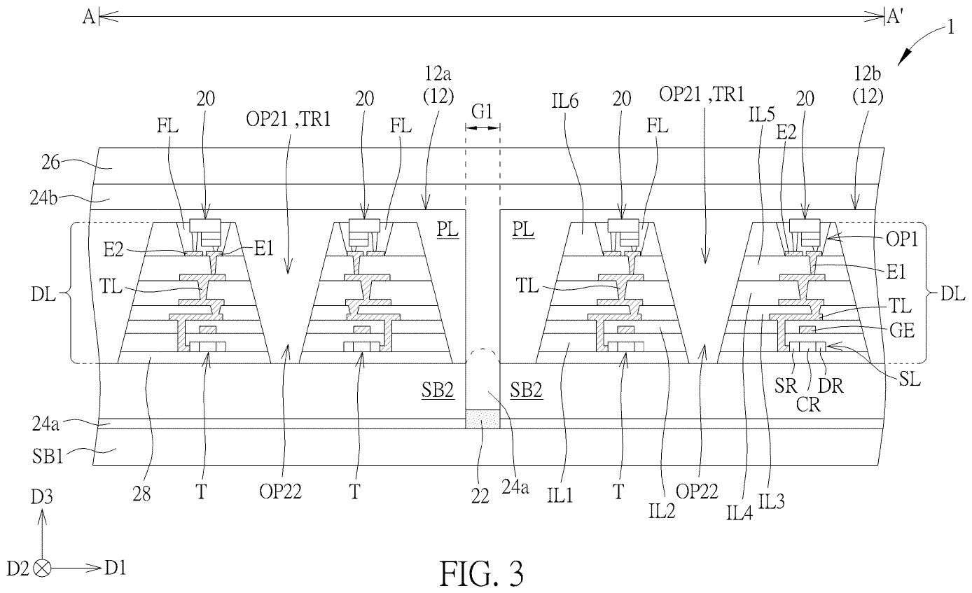

In the following drawings, direction D1, direction D2, and direction D3 are indicated. The direction D3 may represent a normal direction or a top-view direction of a tiled electronic device. As shown in FIG. 3, the direction D3 may be perpendicular to an upper surface of a substrate SB1. The direction D1 and the direction D2 may be horizontal directions and may be perpendicular to the direction D3. As shown in FIG. 3, the direction D1 and the direction D2 may be parallel to the upper surface of the substrate SB1, and the direction D1 and the direction D2 may be perpendicular to each other. The spatial relationships of the structures in the following drawings may be described based on the direction D1, the direction D2, and the direction D3.

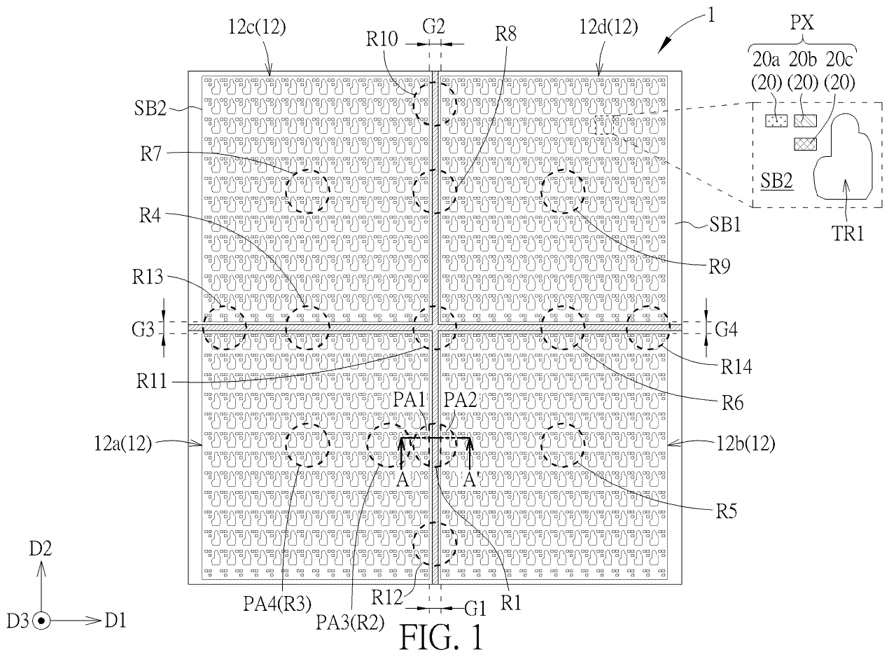

Refer to FIG. 1, which schematically illustrates a cross-sectional view of a tiled electronic device according to a first embodiment of the present disclosure, wherein a right portion of FIG. 1 is an enlarged schematic diagram of a part of left portion of FIG. 1. The tiled electronic device 1 includes a first electronic module 12a and a second electronic module 12b, and the second electronic module 12b may be disposed adjacent to the first electronic module 12a. The first electronic module 12a and the second electronic module 12b may be separated by a gap G1 along a first direction (e.g., the direction D1 or the direction D2). The tiled electronic device 1 includes a first region R1 and a second region R2. The first region R1 includes a portion of the gap G1, a first portion PA1 of the first electronic module 12a adjacent to the gap G1, and a second portion PA2 of the second electronic module 12b adjacent to the gap G1. The second region R2 and the first region R1 are arranged along the first direction, and the second region R2 includes a third portion PA3 of the first electronic module 12a adjacent to the first portion PA1. The first region R1 has a first optical performance P1, and the second region R2 has a second optical performance P2. The first optical performance P1 and the second optical performance P2 may satisfy the relationship (1): |(P1−P2)/P2|≤5%, which enhances the uniformity of the optical performance of the tiled electronic device 1. Accordingly, a user does not easily perceive a visual difference between the first region R1 (which includes the gap G1) and the second region R2 (which does not include the gap G1), thereby improving the visual effect of the tiled electronic device 1. The aforementioned first direction may be a direction perpendicular to an extending direction of the gap G1 in the top view. The aforementioned first portion PA1 may refer to a portion of the first electronic module 12a in the first region R1 but outside the gap G1. The aforementioned second portion PA2 may refer to a portion of the second electronic module 12b in the first region R1 but outside the gap G1. The aforementioned third portion PA3 may refer to a portion of the first electronic module 12a in the second region R2. Furthermore, a diameter of the first region R1 may range from 2 millimeters (mm) to 20 millimeters, i.e., an area of the first region R1 may range from 3.142 square millimeters (mm²) to 314.159 square millimeters. In some embodiments, the first region R1 and the second region R2 may have the same area (or diameter).

Specifically, the tiled electronic device 1 may include a plurality of electronic modules 12 that are tiled with one another, and any two adjacent electronic modules 12 are separated by a gap (e.g., the gap G1, a gap G2, a gap G3, or a gap G4). In FIG. 1, four electronic modules 12 are illustrated as an example and are arranged in an array, but not limited thereto. The first electronic module 12a and the second electronic module 12b may be any adjacent two of the electronic modules 12, for example. In FIG. 1, the first electronic module 12a and the second electronic module 12b are arranged along the direction D1 as an example, but not limited thereto. In some embodiments, the electronic modules 12 may be transparent electronic modules, such as transparent display devices or transparent display panels, which may be capable of exhibiting a transparent state, but not limited thereto. In the present disclosure, the term “transparent” may refer to an electronic module 12 having a transmittance greater than 25% for example with respect to visible light. In some embodiments, the electronic modules 12 may alternatively be electronic devices capable of controlling transparency or transmittance, but not limited thereto.

The tiled electronic device 1 may further include an optical structure 22 disposed corresponding to the gap (e.g., the gap G1), and the optical structure 22 may allow the optical performance P1 of the first region R1 and the second optical performance P2 of the second region R2 to satisfy the aforementioned relationship (1), so as to improve visual effect. In the embodiment of FIG. 1, the optical structure 22 may, for example, be disposed in the gap G1 in a top view of the tiled electronic device 1. In some embodiments, the optical structure 22 may alternatively be disposed in a region of each electronic module adjacent to the gap G1, but not limited thereto.

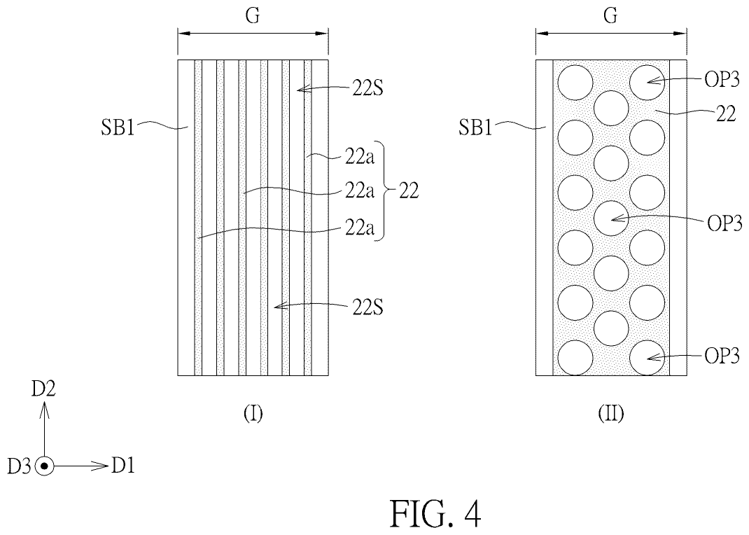

According to this embodiment, the electronic modules 12 may, for example, include a third electronic module 12c and a fourth electronic module 12d, which are disposed adjacent to each other, wherein the first electronic module 12a and the third electronic module 12c may be adjacent to each other and arranged along the second direction, and the second electronic module 12b and the fourth electronic module 12d may be adjacent to each other and arranged along the second direction. The third electronic module 12c and the fourth electronic module 12d may be separated by another gap G2 in the first direction. The first electronic module 12a and the third electronic module 12c are separated by another gap G3, and the second electronic module 12b and the fourth electronic module 12d are also separated by another gap G4. In FIG. 1, the first direction and the second direction may, for example, be the direction D1 and the direction D2, and alternatively, they may be interchanged. Any of the gaps G1, G2, G3 and G4 may be, for example, the gap G shown in FIG. 4 to FIG. 10. In some embodiments, the first, second, third and fourth electronic module 12a, 12b, 12c, 12d may be transparent electronic modules, but not limited thereto. In some embodiments, transmittances of the first, second, third and fourth electronic modules 12a, 12b, 12c, 12d may be greater than 25%.

It should be noted that for easily comparing the first optical performance of the first region R1 and the second optical performance of the second region R2, the top view area of the first region R1 may be the same as that of the second region R2. The top view shape of the first region R1 may, for example, be the same as that of the second region R2. In FIG. 1, the first region R1 and the second region R2 may, for example, have circular top view shape or other suitable shapes. Different regions in the present disclosure may have the same top view area and the same top view shape, but not limited thereto.

As shown in FIG. 1, a center of the first region R1 may, for example, be overlapped with the gap G1 in the top view of the tiled electronic device 1, and the second region R2 is not overlapped with the first region R1. A position of the second region R2 may, for example, be a location where the first region R1 is shifted along direction D1 toward the center of the first electronic module 12a by a distance. A distance between the center of the second region R2 and the center of the first region R1 may, for example, be greater than the diameter of the first region R1 and less than or equal to twice the diameter.

The tiled electronic device 1 may further include a third region R3, wherein the third region R3 includes a fourth portion PA4 of the first electronic module 12a adjacent to the center of the first electronic module 12a. The third region R3 is not overlap with the second region R2 in the top view of the tiled electronic device 1. The center of the third region R3 may, for example, be located in a range where the distance to the center of the first electronic module 12a is less than or equal to 1.5 times the diameter of the third region R3. In FIG. 1, the third region R3, the second region R2, and the first region R1 may, for example, be arranged along the direction D1, and the second region R2 may, for example, be located between the first region R1 and the third region R3, but not limited thereto. The aforementioned fourth portion PA4 may refer to a portion of the first electronic module 12a in the third region R3. In some embodiments, the first region R1, the second region R2, and the third region R3 may have the same area (or diameter).

The third region R3 may have a third optical performance P3, and the second optical performance P2 and the third optical performance P3 may satisfy the relationship (2): |(P2−P3)/P3|≤10%, which enhances the uniformity of the optical performances of the portions of the tiled electronic device 1 corresponding to the first electronic module 12a. In some embodiments, |(P1−P2)/P2| may be referred to as a first difference, and |(P2−P3)/P3| may be referred to as a second difference, and the first difference may be less than or equal to the second difference, such that the uniformity of the optical performances of the portions of the tiled electronic device 1 corresponding to the first electronic module 12a and corresponding to the gap may be improved. In some embodiments, the first optical performance P1 and the third optical performance P3 may further satisfy the relationship (3): |(P1−P3)/P3|≤10%, which improves the uniformity of the optical performances of the portions of the tiled electronic device 1 corresponding to the center of the first electronic module 12a and corresponding to the gap. In some embodiments, |(P1−P3)/P3| may be referred to as a third difference, and the first difference may be less than or equal to the third difference, such that the uniformity of the optical performances of the portions of the tiled electronic device 1 corresponding to the center of the first electronic module 12a and corresponding to the gap may be improved.

The tiled electronic device 1 may further include a fourth region R4, wherein the fourth region R4 may include a portion of the gap G3, a portion of the first electronic module 12a adjacent to the gap G3, and a portion of the third electronic module 12c adjacent to the gap G3. The relationship between the optical performances of the fourth region R4 and the third region R3 may be similar or identical to the relationship between the first optical performance P1 and the third optical performance P3, and therefore may satisfy the relationship (3), wherein P3 may be replaced with the optical performance of the fourth region R4. In some embodiments, the optical performance of a region located between the fourth region R4 and the third region R3 may alternatively satisfy the above-mentioned relationships (1) and (2), wherein P3 may be replaced with the optical performance of the fourth region R4, and P2 may be replaced with the optical performance of the region located between the fourth region R4 and the third region R3. In some embodiments, the first region R1, the second region R2, the third region R3, and the fourth region R4 may have the same area (or diameter).

Similarly, the tiled electronic device 1 may further include a fifth region R5, a sixth region R6, a seventh region R7, an eighth region R8, and a ninth region R9. The fifth region R5 includes a portion of the second electronic module 12b adjacent to the center of the second electronic module 12b. The sixth region R6 includes a portion of the gap G4, a portion of the second electronic module 12b adjacent to the gap G4, and a portion of the fourth electronic module 12d adjacent to the gap G4. The seventh region R7 includes a portion of the third electronic module 12c adjacent to the center of the third electronic module 12c. The eighth region R8 includes a portion of the gap G2, a portion of the third electronic module 12c adjacent to the gap G2, and a portion of the fourth electronic module 12d adjacent to the gap G2. The ninth region R9 includes a portion of the fourth electronic module 12d adjacent to the center of the fourth electronic module 12d. The relationship among the optical performances of the fifth region R5, the first region R1, and a region located between the fifth region R5 and the first region R1, the relationship among the optical performances of the fifth region R5, the sixth region R6, and a region located between the fifth region R5 and the sixth region R6, the relationship among the optical performances of the seventh region R7, the fourth region R4, and a region located between the seventh region R7 and the fourth region R4, the relationship among the optical performances of the seventh region R7, the eighth region R8, and a region located between the seventh region R7 and the eighth region R8, the relationship among the optical performances of the ninth region R9, the sixth region R6, and a region located between the ninth region R9 and the sixth region R6, and the relationship among the optical performances of the ninth region R9, the eighth region R8, and a region located between the ninth region R9 and the eighth region R8 may be similar or identical to the relationships among the first optical performance P1, the second optical performance P2, and the third optical performance P3. Therefore, the above relationships may satisfy the aforementioned relationships (1), (2), and (3), wherein P3 may be replaced with the optical performance of the fifth region R5, the seventh region R7, or the ninth region R9; P2 may be replaced with the optical performance of the region located between the fifth region R5 and the first region R1, the region located between the fifth region R5 and the sixth region R6, the region located between the seventh region R7 and the fourth region R4, the region located between the seventh region R7 and the eighth region R8, the region located between the ninth region R9 and the sixth region R6, or the region located between the ninth region R9 and the eighth region R8; and P1 may be replaced with the optical performance of the fourth region R4, the sixth region R6, or the eighth region R8.

According to this embodiment, the optical structure 22 may further be disposed corresponding to the gaps G2, G3, and G4, such that the optical performances of the fifth region R5, the sixth region R6, the seventh region R7, the eighth region R8, and the ninth region R9 may satisfy the above-mentioned relationships (1), (2), and (3), thereby enhancing the visual effect. In the embodiment shown in FIG. 1, the optical structure 22 may, for example, be disposed in the gaps G2, G3, and G4 in the top view of the tiled electronic device 1. In some embodiments, the optical structure 22 may alternatively be disposed in regions of each electronic module 12 adjacent to the gaps G2, G3, and G4, but not limited thereto. In some embodiments, the first region R1 through the ninth region R9 may have the same area (or diameter).

The tiled electronic device 1 may further include a tenth region R10, an eleventh region R11, and a twelfth region R12. The tenth region R10 may include a portion of the gap G2, a portion of the third electronic module 12c adjacent to the gap G2, and a portion of the fourth electronic module 12d adjacent to the gap G2. The eleventh region R11 may be located at a junction of the gaps G1, G2, G3, and G4 and may include a portion of the gap G1, a portion of the first electronic module 12a adjacent to the gaps G1 and G3, a portion of the second electronic module 12b adjacent to the gaps G1 and G4, a portion of the gap G2, a portion of the third electronic module 12c adjacent to the gaps G2 and G3, a portion of the fourth electronic module 12d adjacent to the gaps G2 and G4, a portion of the gap G3, and a portion of the gap G4. The twelfth region R12 may include a portion of the gap G1, a portion of the first electronic module 12a adjacent to the gap G1, and a portion of the second electronic module 12b adjacent to the gap G1 and be different from the first region R1. In FIG. 1, the twelfth region R12, the first region R1, the eleventh region R11, the eighth region R8, and the tenth region R10 are sequentially arranged along the second direction (e.g., the direction D2). In the direction D2, the maximum value Pmax1, the minimum value Pmin1, and the average value Pave1 of the optical performances of the twelfth region R12, the first region R1, the eleventh region R11, the eighth region R8, and the tenth region R10 may satisfy the relationship (4): |(Pmax1−Pmin1)/Pave1|≤5%. In other words, the uniformity of the optical performances of the portions of the tiled electronic device 1 corresponding to the gaps G1 and G2 extending along direction D2 may be improved. In some embodiments, the first region R1 through the twelfth region R12 may have the same area (or diameter).

The tiled electronic device 1 may further include a thirteenth region R13 and a fourteenth region R14. The thirteenth region R13 may include a portion of the gap G3, a portion of the first electronic module 12a adjacent to the gap G3, and a portion of the third electronic module 12c adjacent to the gap G3. The fourteenth region R14 may include a portion of the gap G4, a portion of the second electronic module 12b adjacent to the gap G4, and a portion of the fourth electronic module 12d adjacent to the gap G4. In FIG. 1, the thirteenth region R13, the fourth region R4, the eleventh region R11, the sixth region R6, and the fourteenth region R14 are sequentially arranged along the first direction (e.g., the direction D1). In the direction D1, the maximum value Pmax2, the minimum value Pmin2, and the average value Pave2 of the optical performances of the thirteenth region R13, the fourth region R4, the eleventh region R11, the sixth region R6, and the fourteenth region R14 may satisfy the relationship (5): |(Pmax2−Pmin2)/Pave2|≤5%. Accordingly, the uniformity of the optical performances of the portions of the tiled electronic device 1 corresponding to the gaps G3 and G4 extending along direction D1 may be improved. In some embodiments, the first region R1 through the fourteenth region R14 may have the same area (or diameter).

In some embodiments, the maximum value Pmax3, the minimum value Pmin3, and the average value Pave3 of the optical performances of the twelfth region R12, the first region R1, the eleventh region R11, the eighth region R8, the tenth region R10, the thirteenth region R13, the fourth region R4, the eleventh region R11, the sixth region R6, and the fourteenth region R14 may satisfy the relationship (5): |(Pmax3−Pmin3)/Pave3|≤5%. In other words, the uniformity of the optical performances of the portions of the tiled electronic device 1 corresponding to the gaps G3 and G4 extending along the direction D1 and the gaps G1 and G2 extending along the direction D2 may be improved. In some embodiments, the average value Pave1 along the direction D2, the average value Pave2 along the direction D1, and the average value Pave3 may satisfy the relationship (6): |(Pave1−Pave2)/Pave3|≤5%.

In some embodiments, the first optical performance P1 of the first region R1, the third optical performance P3 of the third region R3, and the optical performance P5 of the fifth region R5 may satisfy the relationship (7): 95%≤|P3−P1|/|P5−P1|≤105%. Similarly, the relationship among the optical performances of the seventh region R7, the eighth region R8, and the ninth region R9, the relationship among the optical performances of the third region R3, the fourth region R4, and the seventh region R7, and the relationship among the optical performances of the fifth region R5, the sixth region R6, and the ninth region R9 may be similar or identical to the relationship among the first region R1, the third region R3, and the fifth region R5 and may satisfy the relationship (7), wherein P1 may be replaced with the optical performance of the fourth region R4, the sixth region R6, or the eighth region R8; P3 may be replaced with the optical performance of the seventh region R7 or the fifth region R5; and P5 may be replaced with the optical performance of the seventh region R7 or the ninth region R9.

In some embodiments, the maximum value Pmax4, the minimum value Pmin4, and the average value Pave4 of the optical performances of the first region R1, the third region R3, the fifth region R5, the eleventh region R11, the seventh region R7, the eighth region R8, and the ninth region R9 may satisfy the relationship (8): |(Pmax4−Pmin4)/Pave4|≤5%. Similarly, the optical performances of the fourth region R4, the third region R3, the seventh region R7, the eleventh region R11, the sixth region R6, the fifth region R5, and the ninth region R9 may also satisfy the relationship (8).

It should be noted that, since the optical structure 22 may be disposed corresponding to the gaps G1, G2, G3, and G4, the optical performances of the first region R1 through the fourteenth region R14 may satisfy the above relationships, thereby enhancing the visual effect. The optical performances will be further described below.

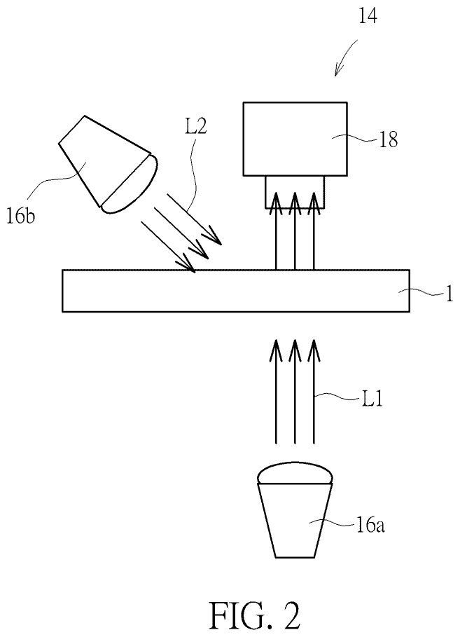

In some embodiments, the optical performances of the first region R1 through the fourteenth region R14 may each be transmittance, reflectance, a combination of transmittance and reflectance, chromaticity, or other visual perception characteristics. Refer to FIG. 2, which schematically illustrates a cross-sectional view of measuring the optical performance of a region of the tiled electronic device according to an embodiment of the present disclosure. As shown in FIG. 2, the tiled electronic device 1 may be disposed in an inspection device 14. In FIG. 2, the optical performance is exemplified as a combination of transmittance and reflectance. The inspection device 14 may include, for example, a light source 16a, a light source 16b, and a light sensor 18. During inspection, the light source 16a and the light sensor 18 may be respectively disposed on opposite sides of the tiled electronic device 1, and the light source 16b and the light sensor 18 may be disposed on the same side of the tiled electronic device 1. A light beam L1 emitted from the light source 16a may pass through a region of the tiled electronic device 1 to be inspected and be received by the light sensor 18. A light beam L2 emitted from the light source 16b may be reflected by the region of the tiled electronic device 1 to be inspected and received by the light sensor 18. Accordingly, the light sensor 18 may simultaneously receive the light beam L1 passing through the tiled electronic device 1 and the light beam L2 reflected by the tiled electronic device 1, and the intensity of light received by the light sensor 18 may represent the optical performance of the region to be inspected, but not limited thereto. In some embodiments, when each optical performance is the transmittance, the light source 16b may be turned off, such that the intensity of the light beam L1 emitted from the light source 16a and passing through the region of the tiled electronic device 1 to be inspected represents the optical performance. In some embodiments, when each optical performance is reflectance, the light source 16a may be turned off, such that the intensity of the light beam L2 emitted from the light source 16b and reflected by the region of the tiled electronic device 1 to be inspected represents the optical performance. In the following description, transmittance is used as an example of the optical performance, but not limited thereto.

The cross-sectional shapes of the light beams L1 and

L2 may be circular or other suitable shapes. When the cross-sectional shapes of the light beams L1 and L2 are circular, a diameter of a spot of each light beam may, for example, range from 2 millimeters (mm) to 20 millimeters, such as 3 mm, 5 mm, 10 mm, 15 mm, or 20 mm. A color of the light beam L1 may be the same as that of the light beam L2 and may be adjusted as needed. For example, the optical performances in any of the aforementioned relationships may be light intensity measured in the case of the light beams L1 and L2 being white light. The wavelength range of the white light may, for example, be in a range from 400 nanometers to 800 nanometers.

In some embodiments, as shown in FIG. 1, the light beams L1 and L2 may be green light, wherein a wavelength range of the green light may, for example, range from 535 nanometers to 575 nanometers. In this case, the first optical performance P1 and the second optical performance P2 may satisfy the relationship (9): |(P1−P2)/P2|≤3%. Since the human eye is more sensitive or has higher distinguishability to green light in a bright environment, the structure satisfying the relationship (9) may reduce the probability that a user perceives a difference between the first region R1 and the second region R2. Similarly, the relationship between the optical performances of the first region R1 and the region between the fifth region R5 and the first region R1, the relationship between the optical performances of the sixth region R6 and the region between the fifth region R5 and the sixth region R6, the relationship between the optical performances of the fourth region R4 and the region between the seventh region R7 and the fourth region R4, the relationship between the optical performances of the eighth region R8 and the region between the seventh region R7 and the eighth region R8, the relationship between the optical performances of the sixth region R6 and the region between the ninth region R9 and the sixth region R6, and the relationship between the optical performances of the eighth region R8 and the region between the ninth region R9 and the eighth region R8 may also satisfy relationship (9), wherein P2 may be replaced with the optical performance of the region between the fifth region R5 and the first region R1, the region between the fifth region R5 and the sixth region R6, the region between the seventh region R7 and the fourth region R4, the region between the seventh region R7 and the eighth region R8, the region between the ninth region R9 and the sixth region R6, or the region between the ninth region R9 and the eighth region R8, and P1 may be replaced with the optical performance of the fourth region R4, the sixth region R6, or the eighth region R8.

In some embodiments, when the light beams L1 and L2 are green light, the second optical performance P2 and the third optical performance P3 may satisfy the relationship (10): |(P2−P3)/P3|≤6%. Similarly, the relationship between the optical performances of the fifth region R5 and the region between the fifth region R5 and the first region R1, the relationship between the optical performances of the fifth region R5 and the region between the fifth region R5 and the sixth region R6, the relationship between the optical performances of the seventh region R7 and the region between the seventh region R7 and the fourth region R4, the relationship between the optical performances of the seventh region R7 and the region between the seventh region R7 and the eighth region R8, the relationship between the optical performances of the ninth region R9 and the region between the ninth region R9 and the sixth region R6, and the relationship between the optical performances of the ninth region R9 and the region between the ninth region R9 and the eighth region R8 may also satisfy the above relationship (10), wherein P3 may be replaced with the optical performance of the fifth region R5, the seventh region R7, or the ninth region R9, and P2 may be replaced with the optical performance of the region between the fifth region R5 and the first region R1, the region between the fifth region R5 and the sixth region R6, the region between the seventh region R7 and the fourth region R4, the region between the seventh region R7 and the eighth region R8, the region between the ninth region R9 and the sixth region R6, or the region between the ninth region R9 and the eighth region R8.

In some embodiments, the light beams may be blue light, wherein the wavelength range of the blue light may be, for example, in a range from 420 nanometers to 440 nanometers. In this case, the first optical performance P1 and the second optical performance P2 may satisfy the relationship (11): |(P1−P2)/P2|≤4%. Since the human eye has lower sensitivity (or resolution) to blue light in a bright environment compared to other colors, the structure satisfying relationship (11) may still reduce the risk that a user perceives a difference between the first region R1 and the second region R2. Similarly, the relationship between the optical performances of the first region R1 and the region between the fifth region R5 and the first region R1, the relationship between the optical performances of the sixth region R6 and the region between the fifth region R5 and the sixth region R6, the relationship between the optical performances of the fourth region R4 and the region between the seventh region R7 and the fourth region R4, the relationship between the optical performances of the eighth region R8 and the region between the seventh region R7 and the eighth region R8, the relationship between the optical performances of the sixth region R6 and the region between the ninth region R9 and the sixth region R6, and the relationship between the optical performances of the eighth region R8 and the region between the ninth region R9 and the eighth region R8 may also satisfy relationship (11), wherein P2 may be replaced with the optical performance of the region between the fifth region R5 and the first region R1, the region between the fifth region R5 and the sixth region R6, the region between the seventh region R7 and the fourth region R4, the region between the seventh region R7 and the eighth region R8, the region between the ninth region R9 and the sixth region R6, or the region between the ninth region R9 and the eighth region R8, and P1 may be replaced with the optical performance of the fourth region R4, the sixth region R6, or the eighth region R8.

In some embodiments, when the light beam is blue light, the second optical performance P2 and the third optical performance P3 may satisfy the relationship (12): |(P2−P3)/P3|≤8%. Similarly, the relationship between the optical performances of the fifth region R5 and the region between the fifth region R5 and the first region R1, the relationship between the optical performances of the fifth region R5 and the region between the fifth region R5 and the sixth region R6, the relationship between the optical performances of the seventh region R7 and the region between the seventh region R7 and the fourth region R4, the relationship between the optical performances of the seventh region R7 and the region between the seventh region R7 and the eighth region R8, the relationship between the optical performances of the ninth region R9 and the region between the ninth region R9 and the sixth region R6, and the relationship between the optical performances of the ninth region R9 and the region between the ninth region R9 and the eighth region R8 may also satisfy the above relationship (12), wherein P3 may be replaced with the optical performance of the fifth region R5, the seventh region R7, or the ninth region R9, and P2 may be replaced with the optical performance of the region between the fifth region R5 and the first region R1, the region between the fifth region R5 and the sixth region R6, the region between the seventh region R7 and the fourth region R4, the region between the seventh region R7 and the eighth region R8, the region between the ninth region R9 and the sixth region R6, or the region between the ninth region R9 and the eighth region R8.

Specifically, as shown in the enlarged schematic view of the right portion of FIG. 1, each electronic module 12 may include a plurality of light emitting units 20. The light emitting units 20 may include, for example, a plurality of light emitting units 20a, a plurality of light emitting units 20b, and a plurality of light emitting units 20c, which are respectively used to generate light of different color. Each electronic module 12 may also include a plurality of transparent regions TR1, and the light emitting units 20 are separated from the transparent regions TR1 in the top view, such that the electronic module 12 may exhibit transparent. According to this embodiment, one of the light emitting units 20a, one of the light emitting units 20b, and one of the light emitting units 20c may serve as different sub-pixels of the same pixel PX, such that each electronic module 12 may display an image. Therefore, the tiled electronic device 1 may display a large-size tiled image, but not limited thereto. In each electronic module 12, the pixels PX may be arranged in an array, and the transparent regions TR1 may also be arranged in an array. The pixels PX and the transparent regions TR1 may be arranged in a staggered manner, but not limited thereto. As shown in FIG. 1, in two adjacent electronic modules 12 arranged along the direction D1, each row of the transparent regions TR1 of one of the electronic modules 12 may be aligned with a corresponding row of the transparent regions TR1 of the other of the electronic modules 12, and each row of the pixels PX of one of the electronic modules 12 may be aligned with a corresponding row of the pixels PX of the other of the electronic modules 12. In two adjacent electronic modules 12 arranged along direction D2, each column of transparent regions TR1 of one of the electronic modules 12 may be aligned with a corresponding column of transparent regions TR1 of the other of the electronic modules 12, and each column of the pixels PX of one of the electronic modules 12 may be aligned with a corresponding column of the pixels PX of the other of the electronic modules 12. The transparent regions TR1 may be regions without a light shielding layer, wherein the transmittance of the light shielding layer is less than 25%. The light shielding layer may, for example, include metal, black resin, black pigment, black dye, or other suitable materials, but not limited thereto.

The light emitting unit 20 may include, for example, a light emitting diode, but not limited thereto. The light emitting diode may include, for example, an organic light emitting diode (OLED), a quantum dot light emitting diode (QLED or QDLED), an inorganic light emitting diode (LED), any other suitable light emitting element, or a combination thereof. The inorganic light emitting diode may include, for example, a sub-millimeter light emitting diode (mini LED) or a micro light emitting diode (micro LED), but not limited thereto. For example, in this embodiment, the light emitting unit 20 may include the inorganic light emitting diode (e.g., micro light emitting diode) and may include two semiconductor layers, an active layer located between the semiconductor layers, an electrode connected to one of the semiconductor layers, and another electrode connected to another of the semiconductor layers, but not limited thereto. In some embodiments, the light emitting unit 20 may include other suitable light emitting materials.

In some embodiments, as shown in FIG. 1, each of the first region R1 to the fourteenth region R14 may have a chromaticity value, and any two of the chromaticity values may satisfy the following relationship (13): Δ(Wx, Wy)≤0.020. For example, when the first region R1 has a chromaticity value (Wx1, Wy1) in the CIE 1931 chromaticity space, and the second region R2 has a chromaticity value (Wx2, Wy2) in the CIE 1931 chromaticity space, Δ(Wx, Wy) of the first region R1 and the second region R2 may be \sqrt{(Wx1−Wx2)²+(Wy1−Wy2)²} and less than or equal to 0.020. In some embodiments, Δ(Wx, Wy) may alternatively be less than or equal to 0.010, or less than or equal to 0.005. In this case, the tiled electronic device 1 may further include a color adjusting layer disposed on a light emitting surface of each light emitting unit (e.g., the light emitting unit 20a, the light emitting unit 20b, and the light emitting unit 20c shown in FIG. 1), so that when the tiled electronic device 1 is in a display state, for example, when displaying an image at 50% of the luminous brightness or at half of the maximum grayscale value, the chromaticity values of different regions may satisfy the relationship (13). The color adjusting layer may, for example, include a color filter material, a pigment, a multilayer film, other suitable materials or structures, or a combination thereof. In some embodiments, the optical structure 22 may include a color filter material, a pigment, a multilayer film, other structures that affect the above-mentioned optical performances, other suitable materials or structures, or a combination thereof, or the color adjusting layer may further be disposed in the transparent region TR1. In this case, when the tiled electronic device 1 is in a non-display state, that is, when the light emitting unit (e.g., the light emitting unit 20a, the light emitting unit 20b, and the light emitting unit 20c shown in FIG. 1) do not generate light, the chromaticity values of different regions may satisfy the relationship (13).

The following will further describe laminated structure of the tiled electronic device. Refer to FIG. 3, which schematically illustrates a cross-sectional view of the tiled electronic device taken along a cross-sectional line A-A′ of FIG. 1 according to the first embodiment of the present disclosure. The tiled electronic device 1 may further include a first optical layer 24a and a second optical layer 24b, wherein the first electronic module 12a and the second electronic module 12b are disposed between the first optical layer 24a and the second optical layer 24b. The first optical layer 24a and the second optical layer 24b may include transparent filling materials, such as silicone glue or other suitable adhesive materials. The first optical layer 24a and the second optical layer 24b may be formed of the same material, for example, to match the optical characteristics of the first optical layer 24a and the second optical layer 24b.

Furthermore, the tiled electronic device 1 may further include a substrate SB1 for supporting the electronic modules 12. In this embodiment, the optical structure 22 may be disposed on the substrate SB1, but not limited thereto. The substrate SB1 may be a transparent substrate, such as a rigid substrate or a flexible substrate. The rigid substrate includes, for example, glass, quartz, sapphire, ceramics, other suitable materials, or a combination thereof. The flexible substrate includes, for example, polyimide (PI) substrate, polycarbonate (PC) substrate, polyethylene terephthalate (PET) substrate, other suitable materials, or a combination thereof, but not limited thereto.

In the embodiment of FIG. 3, the optical structure 22 may include a material that affects the optical performance, such as a material that reduces transmittance. The optical structure 22 may, for example, include a black pigment and a resin, a photoresist material, a color filter material, or other suitable materials, wherein the black pigment is disposed in the resin, and the proportion of the black pigment to the entire optical structure may, for example, range from 5% to 70%, or preferably from 20% to 50%. Although the optical structure 22 may adjust the optical performance of the portion of the tiled electronic device 1 corresponding to the gap, the portion of the tiled electronic device 1 corresponding to the optical structure 22 may still have a transmittance of more than 40%. Accordingly, by disposing the optical structure 22 at a position corresponding to the gap, the optical performance of the portion of the tiled electronic device 1 corresponding to the gap may be matched with the optical performance of the portion of the tiled electronic device 1 corresponding to the electronic module 12, thereby reducing the visibility of the gap and improving the visual effect of the tiled electronic device 1. When the optical structure 22 includes the color filter material, the optical structure 22 may include a stack of color filter materials of different colors, but not limited thereto. In some embodiments, the optical structure 22 may alternatively include a color filter material of a specific color to reduce or prevent chromaticity shift of light after passing through the tiled electronic device 1.

According to this embodiment, the tiled electronic device 1 further includes a third optical layer 26 disposed on the second optical layer 24b. In other words, the first optical layer 24a and the second optical layer 24b are disposed between the substrate SB1 and the third optical layer 26. The third optical layer 26 may, for example, be used to protect the second optical layer 24b and/or provide an optical effect. For example, the third optical layer 26 may be a cover plate, an anti-reflective film, or other suitable optical film. The cover plate may, for example, include a glass substrate or other suitable substrate.

In FIG. 3, each electronic module 12 may include a transparent substrate SB2 and a display layer DL, and the display layer DL may be disposed on the transparent substrate SB2. The display layer DL may, for example, include the plurality of light emitting units 20 shown in FIG. 1 for displaying images, but not limited thereto. The transparent substrate SB2 may include, for example, a rigid substrate or a flexible substrate. The rigid substrate may include, for example, glass, quartz, sapphire, ceramic, other suitable materials, or combinations thereof. The flexible substrate may include, for example, PI substrate, PC substrate, PET substrate, other suitable materials, or combinations thereof, but not limited thereto.

The display layer DL may further include, for example, a buffer layer 28, a plurality of transistors T, a plurality of insulating layers, and a plurality of conductive layers. The buffer layer 28 may be disposed on the transparent substrate SB2. The transistors T may be disposed on the buffer layer 28. The conductive layers may include or form a plurality of traces TL, which pass through some of the insulating layers and are respectively used for electrically connecting the corresponding light emitting units 20 to the corresponding transistors T. In FIG. 3, the insulating layers may include, for example, an insulating layer IL1, an insulating layer IL2, an insulating layer IL3, an insulating layer IL4, an insulating layer IL5, and an insulating layer IL6, and the display layer DL may include a semiconductor layer SL disposed on the buffer layer 28. The semiconductor layer SL may form source regions SR, drain regions DR, and channel regions CR of the transistors T, wherein the source regions SR may be electrically connected to the traces TL, respectively, and further electrically connected to the corresponding light emitting units 20. The insulating layer IL1 may be disposed on the semiconductor layer SL and the buffer layer 28, and serve as a gate insulating layer of the transistor T. The transistor T may include a gate GE, disposed on the insulating layer IL1. The gate GE may be formed of one of the conductive layers, for example. The insulating layer IL2 may be disposed on the gate GE and the insulating layer IL1, and the insulating layer IL3 and the insulating layer IL4 may be sequentially disposed on the insulating layer IL2, wherein the insulating layer IL4, the insulating layer IL3, the insulating layer IL2, and the insulating layer IL1 may respectively have through holes, so that the traces TL may pass through the insulating layer IL4, the insulating layer IL3, the insulating layer IL2, and the insulating layer IL1 to contact the corresponding source regions SR, but not limited thereto. The insulating layer IL5 may be disposed on the traces TL and the insulating layer IL4, and the display layer DL may further include a plurality of electrode pairs disposed on the insulating layer IL5, wherein each electrode pair includes an electrode E1 and an electrode E2. The insulating layer IL5 may have through holes, such that the electrode E1 may pass through the insulating layer IL5 to be electrically connected to the corresponding trace TL. The electrode E1 and the electrode E2 may be formed of another of the conductive layers, for example. The insulating layer IL6 may have a plurality of openings OP1, and each opening OP1 may expose a corresponding electrode pair. The light emitting units 20 may be respectively disposed in the corresponding openings OP1 and bonded with the electrodes E1 and E2 of the corresponding electrode pairs, so as to be further electrically connected to the corresponding transistors T. In other words, the insulating layer IL6 may serve as a pixel defining layer, for example. In FIG. 3, the display layer DL may optionally further include a filling layer FL disposed in the openings OP1, to enhance the bonding strength between the light emitting units 20 and the electrode pairs.

It should be noted that the buffer layer 28, the insulating layer IL1, the insulating layer IL2, and the insulating layer IL3 may include inorganic insulating materials, for example, to reduce the impact of moisture or oxygen on the transistors T. The inorganic insulating materials may include silicon oxide, silicon nitride, aluminum oxide, other suitable materials, or combinations thereof. The buffer layer 28 may include a single-layer or multi-layer structure. The multi-layer structure of the buffer layer 28 may include, for example, sequential stacking of silicon nitride, silicon oxide, and silicon nitride, but not limited thereto. The insulating layer IL4 and the insulating layer IL5 may, for example, include organic insulating materials, which have better planarization effects compared to the inorganic insulating materials. Therefore, the insulating layer IL4 and the insulating layer IL5 may have flat upper surfaces to help form flat electrodes E1 and E2, thereby improving the bonding of the light emitting units 20 with the electrode pairs. The insulating layer IL6 may include an organic insulating material or an inorganic insulating material, but the materials of the insulating layers in the present disclosure are not limited thereto.

In FIG. 3, the insulating layers IL4, IL5, and IL6 including the organic insulating material may have a plurality of openings OP21, such that the openings OP21 may serve as the transparent regions TR1, respectively, but the openings OP21 of the present disclosure are not limited to being formed of the insulating layers IL4, IL5, and IL6 and may be adjusted as needed. The transparent region TR1 may be, for example, a region surrounded by an edge of a lower surface of the lowermost insulating layer IL4, including the organic insulating material, corresponding to the opening OP21. The buffer layer 28 and the insulating layers IL1, IL2, and IL3 may have a plurality of openings OP22, each corresponding to the openings OP21. Since the buffer layer 28 and the insulating layers IL1, IL2, and IL3, including the inorganic insulating material, and the insulating layers IL4, IL5, and IL6, including the organic insulating materials, are stacked separately, it facilitates the formation of the openings OP21 having relatively flat sidewalls in the insulating layers IL4, IL5, and IL6 and the formation of openings OP22 having relatively flat sidewalls in the buffer layer 28 and the insulating layers IL1, IL2, and IL3, but the present disclosure is not limited thereto. In some embodiments, at least one of the insulating layers IL1, IL2, IL3, and the buffer layer 28 may be overlapped with the transparent region TR1 or the opening OP21 in the direction D3.

According to this embodiment, the electronic module 12 may further include a package layer PL disposed on the display layer DL and the transparent substrate SB2 to protect the display layer DL, but the present disclosure is not limited thereto. The package layer PL may include a transparent encapsulation material, such as resin, epoxy resin, epoxy molding compound (EMC), other suitable materials, or a combination thereof.

The following contents further describe a manufacturing method of the tiled electronic device 1 of this embodiment. As shown in FIG. 3, the manufacturing method of the tiled electronic device 1 may include providing the substrate SB1, forming the first optical layer 24a on the substrate SB1, disposing a plurality of electronic modules 12 on the first optical layer 24a, forming the second optical layer 24b on the electronic modules 12, and forming the third optical layer 26 on the second optical layer 24b. The manufacturing method of the present disclosure is not limited to the aforementioned steps, and other steps may be performed before, after, or during any of the aforementioned steps.

In FIG. 3, the optical structure 22 may be formed on the substrate SB1 between the steps of providing the substrate SB1 and forming the first optical layer 24a. It is noted that in the step of disposing the electronic modules 12, the optical structure 22 may serve as an alignment mark to facilitate alignments of the electronic modules 12. In this embodiment, the electronic modules 12 may not overlap the optical structure 22 in the direction D3, but not limited thereto. Additionally, the step of disposing the electronic modules 12 may optionally include pressing the electronic modules 12 downward, such that there is no air gap between the electronic modules 12 and the first optical layer 24a.

When the third optical layer 26 includes the rigid substrate, the step of forming the third optical layer 26 may include pressing the rigid substrate downward, such that there is no air gap between the first optical layer 24a and the second optical layer 24b, between the second optical layer 24b and the electronic modules 12, and between the third optical layer 26 and the second optical layer 24b.

It should be noted that since the optical structure 22 has a property of affecting the optical performance, by disposing the optical structure 22 corresponding to the gap between the electronic modules 12, the uniformity of the optical performance of the tiled electronic device 1 may be improved. Therefore, the user is not easy to notice the difference in optical performance between a region including the gap and a region without including the gap, so as to improve the uniformity of the optical performance of the tiled electronic device 1.

It is noted that the elements and/or layers included in the tiled electronic device 1 of this embodiment are not limited to those described above and may further include other elements and/or layers applicable to the tiled electronic device 1. Other embodiments or variant embodiments of the present disclosure are further described below. To simplify the description, same element or layer in the following embodiments will use the same symbol and will not be repeated. The differences between the aforementioned embodiment and other embodiments or variant embodiments will be described in detail below.

Refer to FIG. 4, which schematically illustrates a top view of the optical structure according to some embodiments of the present disclosure. As shown in portion (I) of FIG. 4, the optical structure 22 corresponding to the gap G may include a plurality of light adjusting strips 22a, and a slit 22S exists between any two of the light adjusting strips 22a. As shown in portion (II) of FIG. 4, the optical structure 22 corresponding to the gap G may include a plurality of openings OP3, wherein a top view shape of the opening OP3 may be, for example, circular or other suitable shapes. The optical structure 22 shown in FIG. 4 may alternatively be applied to any of the tiled electronic devices in the embodiments mentioned above or below.

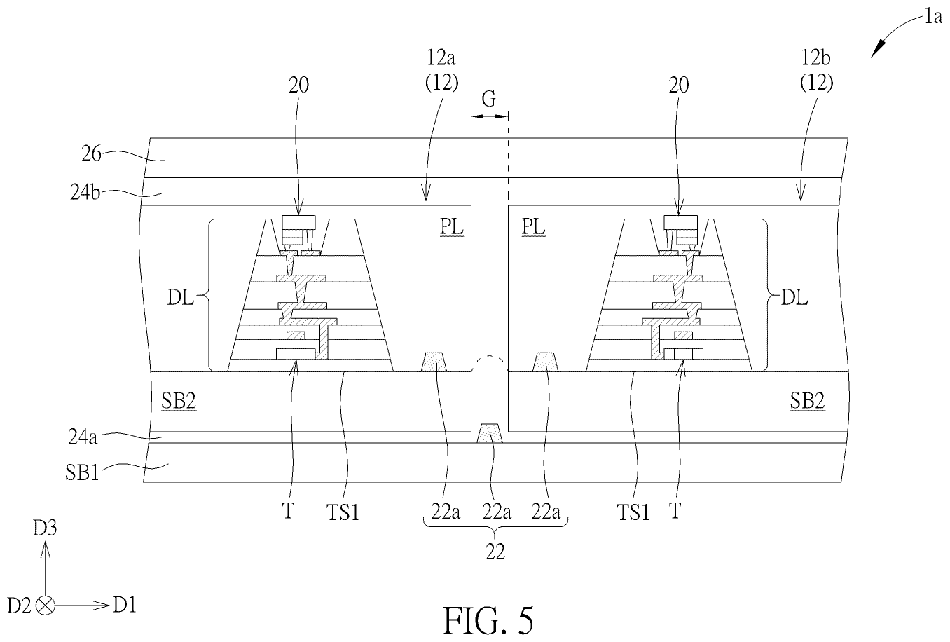

Refer to FIG. 5, which schematically illustrates a cross-sectional view of a tiled electronic device according to a first variant embodiment of the first embodiment of the present disclosure. In the tiled electronic device 1a of this variant embodiment, the optical structure 22 may include a plurality of light adjusting strips 22a, wherein at least one of the light adjusting strips 22a overlaps the gap G, and at least another of the light adjusting strips 22a may be disposed in one of the electronic modules 12 and located on the upper surface TS1 of the transparent substrate SB2 adjacent to the gap G. For example, the light adjusting strips 22a located in two adjacent electronic modules 12 may be disposed adjacent to the corresponding gap G, so that the light adjusting strips 22a may form a plurality of light shielding stripes corresponding to the gap G to adjust the optical performance of the portion of the tiled electronic device 1a corresponding to the gap G. In FIG. 5, the light adjusting strips 22a may be located between the transparent substrate SB2 and the package layer PL, but not limited thereto. The optical structure 22 shown in FIG. 5 may alternatively be applied to any of the tiled electronic devices in the embodiments mentioned above or below.

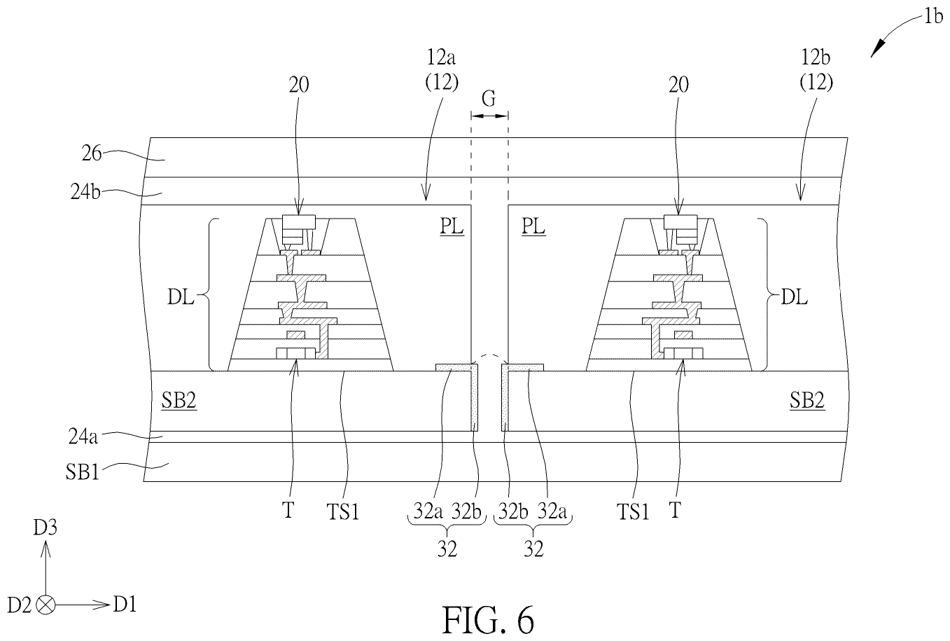

Refer to FIG. 6, which schematically illustrates a cross-sectional view of a tiled electronic device according to a second variant embodiment of the first embodiment of the present disclosure. In this variant embodiment of the tiled electronic device 1b, the electronic module 12 may further include an optical adjusting structure 32 disposed on the upper surface TS1 of the transparent substrate SB2 adjacent to the gap G and on a side surface SW1 facing the gap G. For example, the optical adjusting structure 32 may include a first sub-portion 32a and a second sub-portion 32b, wherein the first sub-portion 32a is disposed on the upper surface TS1 of the transparent substrate SB2, and the second sub-portion 32b is disposed on the side surface SW1 of the transparent substrate SB2. Through the optical adjusting structure 32, the optical performance of the tiled electronic device 1b corresponding to the gap G may be adjusted, for example adjusting the wavelength of light passing through the portion of the tiled electronic device 1b corresponding to the gap G or the transmittance of this portion. The material of the optical adjusting structure 32 may be the same as or similar to the optical structure 22 of FIG. 1, and the reference may be made in the above-mentioned contents and will not be repeated here. In some embodiments, the optical adjusting structure 32 may optionally not include the first sub-portion 32a. The optical adjusting structure 32 shown in FIG. 6 may alternatively be applied to any of the tiled electronic devices in the embodiments mentioned above or below.

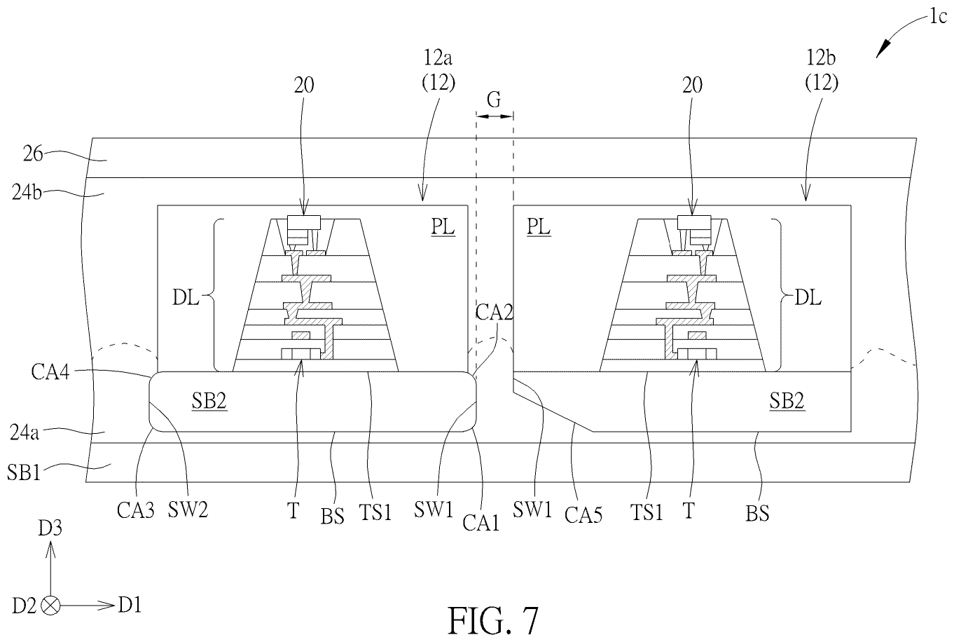

Refer to FIG. 7, which schematically illustrates a cross-sectional view of a tiled electronic device according to a third variant embodiment of the first embodiment of the present disclosure. In this variant embodiment of the tiled electronic device 1c, a corner CA1 and/or a corner CA2 of the transparent substrate SB2 of at least one of the electronic modules 12 (e.g., the left electronic module 12) adjacent to the gap G is a rounded corner, so that the optical performances of the portions of the tiled electronic device 1 corresponding to this electronic module 12 and corresponding to the gap G do not have a significant difference, thereby reducing the visibility of the gap G. In FIG. 7, the corners CA1 and CA2 may be, for example, the corners formed by a lower surface BS and the side surface SW1 of the transparent substrate SB2 respectively facing the substrate SB1 and the gap G and formed by the upper surface TS1 and the side surface SW1 of the transparent substrate SB2 respectively facing the display layer DL and the gap G. In some embodiments, the transparent substrate SB2 may alternatively have a rounded corner CA3 opposite to the corner CA1 and/or a rounded corner CA4 opposite to the corner CA2, but not limited thereto.

In this variant embodiment of the tiled electronic device 1c, a corner CA5 of the transparent substrate SB2 of at least one of the electronic module 12 (e.g., the right electronic module 12) adjacent to the gap G may be a chamfered corner, so that a thickness of the transparent substrate SB2 gradually increases from the gap G towards a center of this electronic module 12. Therefore, the optical performances of the portions of the tiled electronic device 1 corresponding to this electronic module 12 and the gap G do not have a significant difference. For example, the optical performance of the tiled electronic device 1c along a horizontal direction (e.g., the direction D1) may be changed linearly, thereby reducing the visibility of the gap G. In FIG. 7, the corner CA5 may be, for example, the corner formed by the lower surface BS and the side surface SW1 of the transparent substrate SB2 respectively facing the substrate SB1 and the gap G to avoid the chamfered corner affecting the formation quality of the display layer DL and the package layer PL. In some embodiments, the tiled electronic device 1c may optionally have only the rounded corners (e.g., the corners CA1 and/or CA2) or the chamfered corner CA5. The corners CA1 and/or CA2 or the chamfered corner CA5 shown in FIG. 7 may alternatively be applied to any of the tiled electronic devices in the embodiments mentioned above or below.

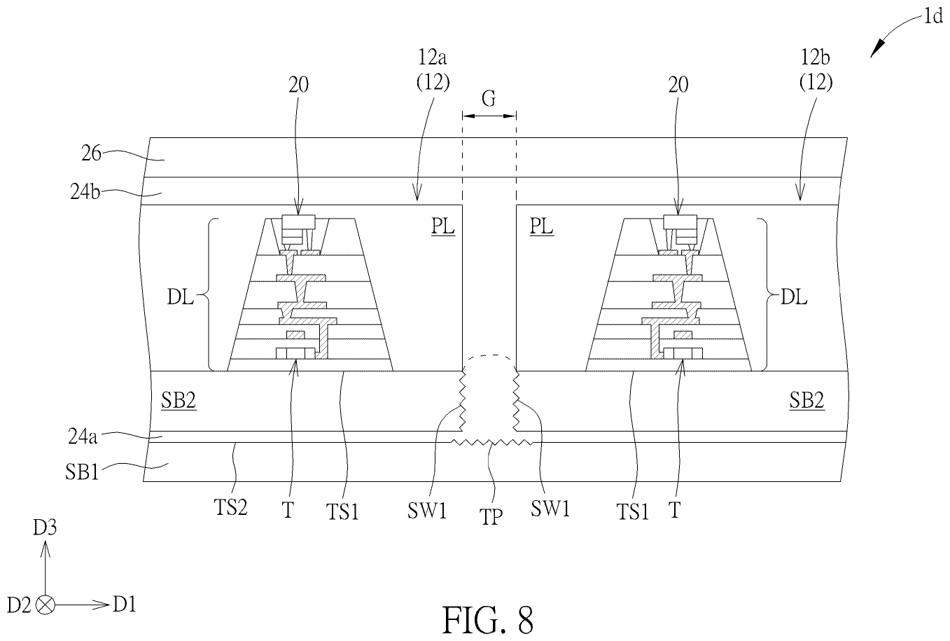

Refer to FIG. 8, which schematically illustrates a cross-sectional view of a tiled electronic device according to a fourth variant embodiment of the first embodiment of the present disclosure. In this variant embodiment of the tiled electronic device 1d, the side surface SW1 of the transparent substrate SB2 of the electronic module 12 facing the gap G may further have a rough surface, such that light may undergo destructive interference when passing through the rough surface, thereby adjusting the optical performance (e.g., transmittance) of the portion of the tiled electronic device 1d corresponding to the gap G. For example, the roughness of the side surface SW1 may be greater than the roughness of the upper surface TS1 of the transparent substrate SB2.

In FIG. 8, a portion TP of the upper surface TS2 of the substrate SB1 corresponding to the gap G may also have a rough surface to adjust the optical performance (e.g., transmittance) of the portion of the tiled electronic device 1d corresponding to the gap G. In some embodiments, the tiled electronic device 1d may optionally only have the rough side surface SW1 or the rough portion TP of the upper surface TS2 corresponding to the gap G. The rough side surface SW1 and/or the rough portion TP of the upper surface TS2 shown in FIG. 8 may alternatively be applied to any of the tiled electronic devices of the embodiments mentioned above or below.

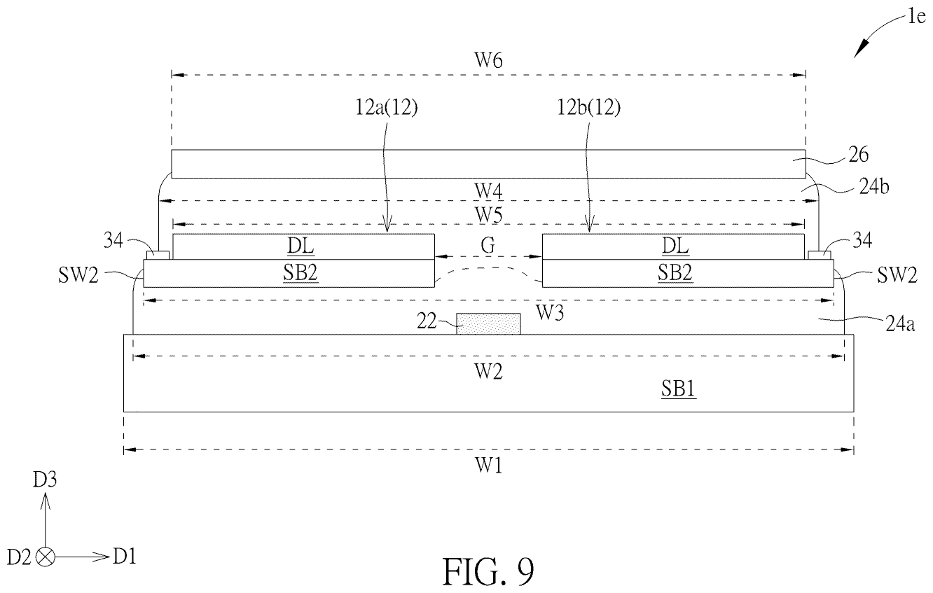

Refer to FIG. 9, which schematically illustrates a cross-sectional view of a tiled electronic device according to a fifth variant embodiment of the first embodiment of the present disclosure. In the tiled electronic device 1e of this variant embodiment, the substrate SB1 may have a width W1 in the horizontal direction, the first optical layer 24a may have a width W2 in the horizontal direction, and the electronic modules 12 may have a distribution width W3 in the horizontal direction. The distribution width W3 may refer to a distance between an outer side surface SW2 of the transparent substrate SB2 of the outermost electronic module 12 (e.g., the first electronic module 12a in FIG. 3) adjacent to an edge of the substrate SB1 to an outer side surface SW2 of the transparent substrate SB2 of another outermost electronic module 12 (e.g., the second electronic module 12b in FIG. 3) adjacent to another edge of the substrate SB1 in the horizontal direction. The horizontal direction in FIG. 9 is exemplified as the direction D1, but not limited thereto. In some embodiments, the horizontal direction may alternatively be the direction D2.

According to this variant embodiment, the width W1 may be greater than or equal to the width W2, allowing the first optical layer 24a to be located on the substrate SB1. Furthermore, the distribution width W3 may be less than or equal to the width W2, allowing each electronic module 12 to be disposed on and overlap the first optical layer 24a, thereby improving the uniformity of the optical performances of the portions of the tiled electronic device 1 corresponding to the electronic modules 12.

In some embodiments, each electronic module 12 may further include a conductive member 34 disposed on the transparent substrate SB2 and adjacent to the outer side surface SW2. The conductive member 34 may be, for example, a chip on film (COF) or other types of conductive structures, but not limited thereto. The COF may be, for example, a flexible circuit board with a chip mounted thereon. It should be noted that the second optical layer 24b has a width W4 in the horizontal direction, and the distribution width W3 may be greater than or equal to the width W4, so that the conductive member 34 may be exposed, which may help dissipate heat from the conductive member 34 or facilitate replacement of the conductive member 34 or the chip thereon when the conductive member 34 does not operate properly.

In some embodiments, the display layers DL of the electronic modules 12 may have another distribution width W5 in the horizontal direction, and the third optical layer 26 may have a width W6 in the horizontal direction. The width W6 is greater than or equal to the distribution width W5, to uniformize the effects of the images displayed by the display layers DL. The relationships among the width W1, the width W2, and the distribution width W3, between the distribution width W3 and the width W4, and/or between the distribution width W5 and the width W6 shown in FIG. 9 may alternatively be applied to any of the tiled electronic devices in the embodiments mentioned above or below. In some embodiments, the above-mentioned widths W1 to W6 may be the maximum widths of the corresponding elements in the top view, or the maximum widths in a direction parallel to the substrate SB1 in the cross-sectional view.

In some embodiments, the substrate SB1 has a first refractive index n1; the transparent substrate SB2 has a second refractive index n2; the first optical layer 24a has a third refractive index n3; and the second optical layer 24b has a fourth refractive index n4. The third refractive index n3 and the fourth refractive index n4 may be adjusted based on the first refractive index n1 and the second refractive index n2, to enhance the transparency of the tiled electronic device 1. A deflection angle of light when passing through the tiled electronic device 1 may be less than or equal to 5 degrees. For example, the first refractive index n1, the second refractive index n2, and the third refractive index n3 satisfy the relationship (14): [(n1+n2)/2]−0.05≤n3≤[(n1+n2)/2]+0.05. The third refractive index n3 and the fourth refractive index n4 satisfy the relationship (15): n3−0.05≤n4≤n3+0.05. When the substrate SB1 and the transparent substrate SB2 include glass, the first refractive index n1 and the second refractive index n2 may be, for example, 1.48 to 1.52, and the third refractive index n3 and the fourth refractive index n4 may be, for example, approximately 1.5. The aforementioned relationships among the first refractive index n1, the second refractive index n2,the third refractive index n3, and the fourth refractive index n4 may also be applied to any of the tiled electronic devices in embodiments mentioned above or below.

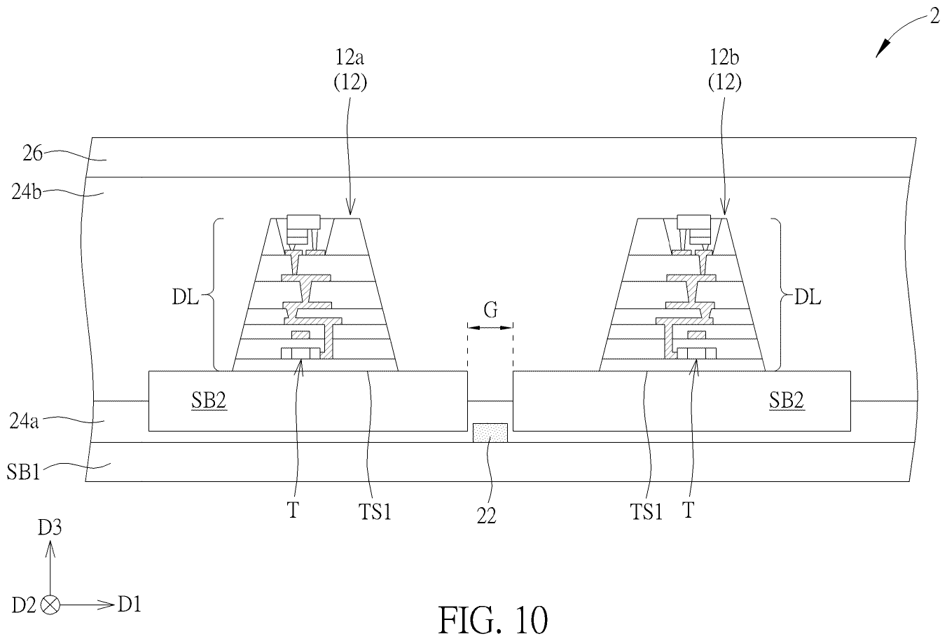

Refer to FIG. 10, which schematically illustrates a cross-sectional view of a tiled electronic device according to a second embodiment of the present disclosure. The tiled electronic device 2 provided in this embodiment differs from the tiled electronic device 1 of FIG. 3 in that the second optical layer 24b may serve as the package layer. Hence, the tiled electronic device 2 may not include the package layer PL shown in FIG. 3, and the second optical layer 24b may contact the display layer DL and the transparent substrate SB2. The second optical layer 24b may include, for example, an optical clear adhesive (OCA), an optical clear resin (OCR), other suitable materials, or a combination thereof.

In the manufacturing method of the tiled electronic device 2 of this embodiment, the electronic modules 12 disposed on the first optical layer 24a may not include the package layer, and the second optical layer 24b may cover the display layers DL and the transparent substrates SB2. Other portions of the tiled electronic device 2 and its manufacturing method of this embodiment are identical to the tiled electronic device 1 and its manufacturing method of FIG. 3, so the reference may be made in the contents mentioned above and will not be repeated here. The second optical layer 24b shown in FIG. 10 may be applied to any of the tiled electronic devices in the embodiments described above or below.

In summary, in the tiled electronic device of the present disclosure, since the optical performances of the portions of the tiled electronic device corresponding to the center of the electronic module, corresponding to the gap, and corresponding to a position located between the center of the electronic module and the gap may satisfy the relationships mentioned above, the uniformity of the optical performance of the tiled electronic device may be increased to improve the visual effect of the tiled electronic device. In addition, through the optical structure, the light adjusting strips, the light adjusting structure, the rounded or chamfered corners or rough side surfaces of the transparent substrate of the electronic module, the rough upper surface of the substrate corresponding to the gap, or the insulating layers including the inorganic material, the optical performance of the portion of the tiled electronic device corresponding to the gap may be adjusted to match the optical performance of the portion of the tiled electronic device corresponding to the electronic module, thereby improving the uniformity of the optical performance of the tiled electronic device.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A tiled electronic device, comprising:
a first electronic module; and
a second electronic module disposed adjacent to the first electronic module, wherein the first electronic module and the second electronic module are separated by a gap in a first direction;
wherein the tiled electronic device comprises a first region and a second region, the first region comprises a portion of the gap, a first portion of the first electronic module adjacent to the gap, and a second portion of the second module adjacent to the gap, the second region and the first region are arranged along the first direction, wherein the second region comprises a third portion of the first module adjacent to the first portion, the first region has a first optical performance P1, the second region has a second optical performance P2, the first optical performance P1 and the second optical performance P2 satisfy a following relationship: |(P1−P2)/P2|≤5%.

2. The tiled electronic device according to claim 1, wherein the first optical performance and the second performance are transmittances.

3. The tiled electronic device according to claim 1, wherein the first optical performance and the second performance are reflectances.

4. The tiled electronic device according to claim 1, wherein the tiled electronic device comprises a third region, the third region comprises a fourth portion of the first electronic module adjacent to a center of the first electronic module, the third region has a third optical performance P3, the second optical performance P2 and the third optical performance P3 satisfy a following relationship:
$$\vert ( P 2 - P 3 ) / P 3 \vert \leq 10 \% .$$

5. The tiled electronic device according to claim 4, wherein the first optical performance P1 and the third optical performance P3 satisfy a following relationship:
$$\vert ( P 1 - P 3 ) / P 3 \vert \leq 10 \% .$$

6. The tiled electronic device according to claim 5, wherein the first optical performance, the second optical performance, and the third optical performance are transmittances.

7. The tiled electronic device according to claim 5, wherein the first optical performance, the second optical performance, and the third optical performance are reflectances.

8. The tiled electronic device according to claim 1, further comprising an optical structure disposed corresponding to the gap.

9. The tiled electronic device according to claim 8, wherein the optical structure comprises a plurality of light adjusting strips or a plurality of openings.

10. The tiled electronic device according to claim 8, wherein the optical structure comprises a black pigment and a resin, and the black pigment is disposed in the resin, wherein a proportion of the black pigment to the optical structure ranges from 5% to 70%.

11. The tiled electronic device according to claim 1, further comprising a first optical layer and a second optical layer, wherein the first electronic module and the second electronic module are disposed between the first optical layer and the second optical layer.

12. The tiled electronic device according to claim 11, further comprising a substrate and a third optical layer, wherein the first optical layer and the second optical layer are disposed between the substrate and the third optical layer.

13. The tiled electronic device according to claim 12, wherein the first electronic module comprises a transparent substrate, the substrate has a first refractive index n1, the transparent substrate has a second refractive index n2, the first optical layer has a third refractive index n3, and the first refractive index n1, the second refractive index n2, and the third refractive index n3 satisfy a following relationship: [(n1+n2)/2]−0.05≤n3≤[(n1+n2)/2]+0.05.

14. The tiled electronic device according to claim 13, wherein the second optical layer has a fourth refractive index n4, and the third refractive index n3 and the fourth refractive index n4 satisfy a following relationship: n3−0.05≤n4≤n3+0.05.

15. The tiled electronic device according to claim 11, wherein the first optical layer has a width in the first direction, the first electronic module and the second electronic module have a distribution width in the first direction, and the distribution width is less than or equal to the width.

16. The tiled electronic device according to claim 11, wherein the second optical layer has a width in the first direction, the first electronic module and the second electronic module have a distribution width in the first direction, and the distribution width is greater than or equal to the width.

17. The tiled electronic device according to claim 1, wherein the first electronic module comprises a plurality of light emitting units and a plurality of first transparent regions, and the plurality of light emitting units are separated from the plurality of first transparent regions in a top view of the tiled electronic device.
